(19) United States
(12) Patent Application Publication
(10) Pub. No.: US 2006/0197229 A1
(43) Pub. Date: Sep. 7, 2006

(54) Semiconductor device

(75) Inventors: Takatoshi Osumi, Nara (JP); Yasuyuki Sakashita, Shiga (JP)

Correspondence Address: STEPTOE & JOHNSON LLP, 1330 CONNECTICUT AVE., NW, WASHINGTON, DC, 20036, US

(73) Assignee: Matsushita Electric Industrial Co., Ltd., Kadoma-shi (JP)

(21) Appl. No.: 11/363,090

(22) Filed: Feb. 28, 2006

(30) Foreign Application Priority Data
Mar. 1, 2005 (JP) 2005-055233

(51) Int. Cl. H01L 23/48

(52) U.S. Cl. 257/773

(57) ABSTRACT

According to the present invention, one or more reinforcing vias (7) or reinforcing metal layers are disposed on the inner side of connecting electrodes (5). With this configuration, strength increases relative to a load applied for mounting a semiconductor element (3) and the sinking of the connecting electrodes (5) is reduced. Thus, it is possible to reduce the connecting stress of the semiconductor device, reduce the deformation of a joint, and increase flexibility in process design.

### FIELD OF THE INVENTION

The present invention relates to a semiconductor device which makes it possible to protect the integrated circuit of an LSI chip, obtain stable electrical connection between an external device and the LSI chip, and achieve high-density packaging, and particularly relates to a semiconductor device for mounting a semiconductor element having a number of connecting terminals.

### BACKGROUND OF THE INVENTION

In recent years, miniaturization has been strongly demanded in the fields of information communications equipment, office electronic equipment, domestic electronic equipment, measurement equipment, industrial electronic equipment such as assembly robots, medical electronic equipment, and electronic toys, and thus semiconductor devices with smaller footprints have been strongly demanded. In response to such needs, Ball Grid Array (BGA) and so on have been used. Semiconductor elements mounted on BGA packages increase in density, and accordingly are requested to respond to smaller chips and a larger number of pins.

Referring to FIG. 8, the following will describe an example of response to the needs according to conventional art.

FIG. 8 is a sectional view showing the structure of a conventional semiconductor device.

As shown in FIG. 8, on a substrate 1 comprising on one main surface a wiring circuit 11 including connecting electrodes 5, a semiconductor element 3 including connecting terminals 4 is mounted facedown so as to electrically connect the connecting electrodes 5 and the connecting terminals 4, the connecting electrodes 5 and connecting vias 6 in the substrate 1 are electrically connected to each other, and the connecting vias 6 and external terminals 10 are connected to each other (For example, JP7-302858A).

In this invention, however, the electrodes sink in the conventional semiconductor device as shown in FIG. 7. Under the connecting electrodes 5, the substrate only has a fiber reinforced resin layer made of glass cloth laminated epoxy, nonwoven aramid fabric and so on with a low strength. Thus, a load applied for mounting the semiconductor element 3 sinks the connecting electrodes 5 into the substrate 1. Thus, the connecting terminals 4 are reduced in height and the semiconductor element 3 is deformed, so that the semiconductor element 3 and the substrate 1 are more likely to come into contact with each other.

Therefore, in consideration of a larger number of pins and narrower pitch, it has become difficult to design structures so as to respond to a connecting load increased for electrical connections according to a growing number of joints, which reduces flexibility in designing the structures of semiconductor devices.

In view of this problem, it is an object of the present invention to reduce connecting stress of a semiconductor device, reduce deformation of a joint, and accordingly improve flexibility in designing the semiconductor device.

### DISCLOSURE OF THE INVENTION

In order to attain the object, a semiconductor device according to a first invention of the present invention, in which one or more semiconductor elements are mounted facedown on a substrate, the semiconductor element including a plurality of connecting terminals, the substrate comprising: a plurality of connecting electrodes formed on one main surface of the substrate electrically connected to the connecting terminals, a plurality of external terminals formed on the other main surface of the substrate, a plurality of connecting vias for electrically connecting the external terminals and the corresponding connecting electrodes, and reinforcing vias formed in an area under the connecting electrodes other than areas where the connecting vias are formed in the substrate. According to the present invention, it is possible to increase strength in the substrate under the connecting electrodes, reduce the sinking of the connecting electrodes, and reduce the warpage of the substrate and the semiconductor element due to smaller deformation.

According to a second invention, in the semiconductor device of the first invention, the reinforcing vias are connected in an electrically insulated manner from the connecting electrodes. According to the present invention, since the insulation of the reinforcing vias is kept, it is possible to increase strength in the substrate under the connecting electrodes, reduce the sinking of the connecting electrodes, and reduce the warpage of the substrate and the semiconductor element due to smaller deformation while keeping an electrically stable state.

According to a third invention, in the semiconductor device of the first invention, the reinforcing vias are electrically connected to the connecting electrodes. According to the present invention, since the long reinforcing vias are disposed immediately below the connecting electrodes, it is possible to increase strength in the substrate under the connecting electrodes, reduce the sinking of the connecting electrodes, and reduce the warpage of the substrate and the semiconductor element due to smaller deformation. Since the reinforcing vias do not reach the side of the external terminals, the number of the external terminals is not limited.

According to a fourth invention, in the semiconductor device of any one of the first to third inventions, the reinforcing vias are wired to the other main surface of the substrate. According to the present invention, the reinforcing vias are present immediately below the connecting electrodes. The reinforcing vias can be disposed, on the inner sides of the connecting electrodes, with a length corresponding to the thickness of the substrate, and thus it is possible to increase strength in the substrate under the connecting electrodes, reduce the sinking of the connecting electrodes, and reduce the warpage of the substrate and the semiconductor element due to smaller deformation. Since the reinforcing vias to the mounted substrate reach the side of the external terminals, external terminals may be provided to improve heat dissipation and reinforce connection.

According to a fifth invention, in the semiconductor device of any one of the first to fourth inventions, the two or more reinforcing vias are formed for each of the connecting electrodes. According to the present invention, since the reinforcing vias in two or more rows are disposed on the inner sides of the connecting electrodes, it is possible to increase strength in the substrate under the connecting electrodes, reduce the sinking of the connecting electrodes, and reduce the warpage of the substrate and the semiconductor element due to smaller deformation.

A sixth invention is a semiconductor device in which one or more semiconductor elements are mounted facedown on a substrate, the semiconductor element including a plurality of connecting terminals, the substrate comprising: a plurality of connecting electrodes formed on one main surface of the substrate electrically connected to the connecting terminals, a plurality of external terminals formed on the other main surface of the substrate, a plurality of connecting vias for electrically connecting the external terminals and the corresponding connecting electrodes, and one or more reinforcing metal layers formed so as to be electrically insulated in an area under the connecting electrodes in the substrate.

According to a seventh invention, in the semiconductor device of the sixth invention, the reinforcing layer is made of a metal.

According to an eighth invention, in the semiconductor device of the sixth invention, the reinforcing layer is made of an insulating material.

According to the present invention, since a reinforcing plate is disposed in each layer on the inner sides of the connecting electrodes, it is possible to increase strength in the substrate under the connecting electrodes, reduce the sinking of the connecting electrodes, and reduce the warpage of the substrate and the semiconductor element due to smaller deformation. The reinforcing metal layer may be disposed like a ring along a row of the connecting electrodes.

As described above, it is possible to reduce the connecting stress of the semiconductor device and reduce the deformation of a joint, thereby increasing flexibility in the structural design of the semiconductor device.

### BRIEF DESCRIPTION OF THE DRAWINGS

FIG. 1 is a sectional view showing the configuration of a semiconductor device according to Embodiment 1 of the present invention;

FIG. 2 is a sectional view showing the configuration of a semiconductor device according to Embodiment 2 of the present invention;

FIG. 3 is a sectional view showing the configuration of a semiconductor device according to Embodiment 3 of the present invention;

FIG. 4 is a sectional view showing the configuration of a semiconductor device according to Embodiment 4 of the present invention;

FIG. 5 is a sectional view showing the configuration of a semiconductor device according to Embodiment 5 of the present invention;

FIG. 6 is a sectional view showing the configuration of a semiconductor device according to Embodiment 6 of the present invention;

FIG. 7 is an explanatory drawing for explaining the sinking of electrodes in a conventional semiconductor device; and

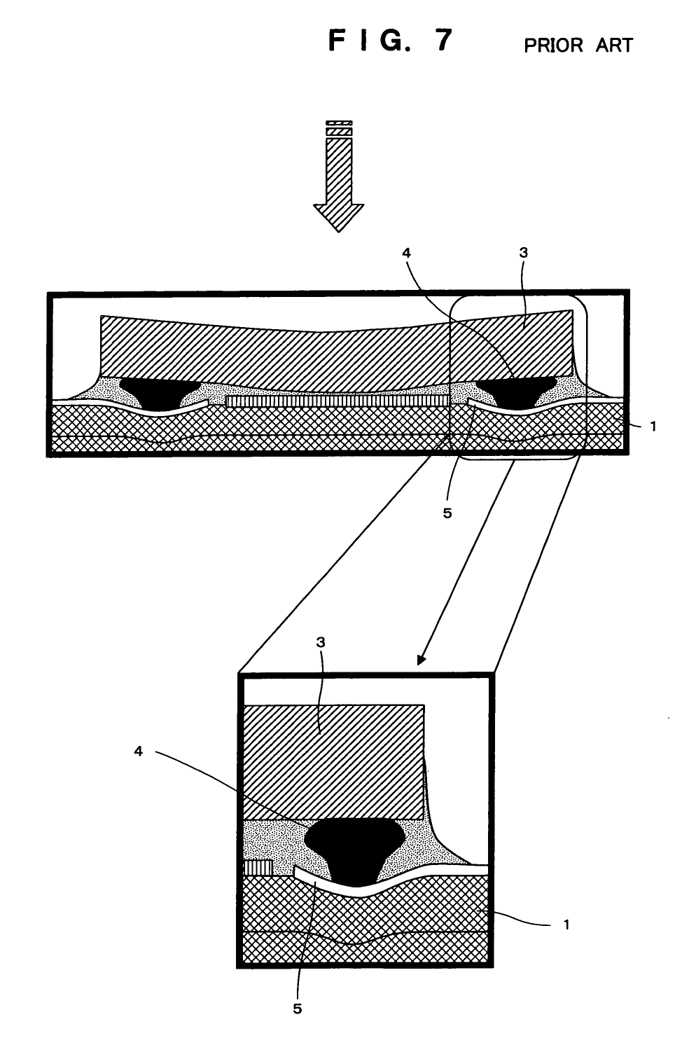

FIG. 8 is a sectional view showing the configuration of the conventional semiconductor device.

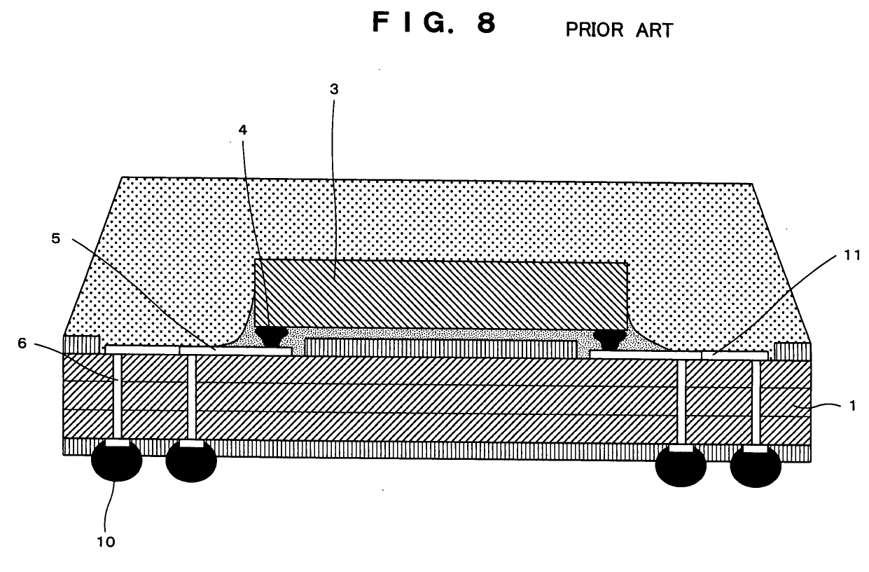

### DESCRIPTION OF THE EMBODIMENTS

The following will describe a semiconductor device according to embodiments of the present invention with reference to the accompanying drawings.

### Embodiment 1

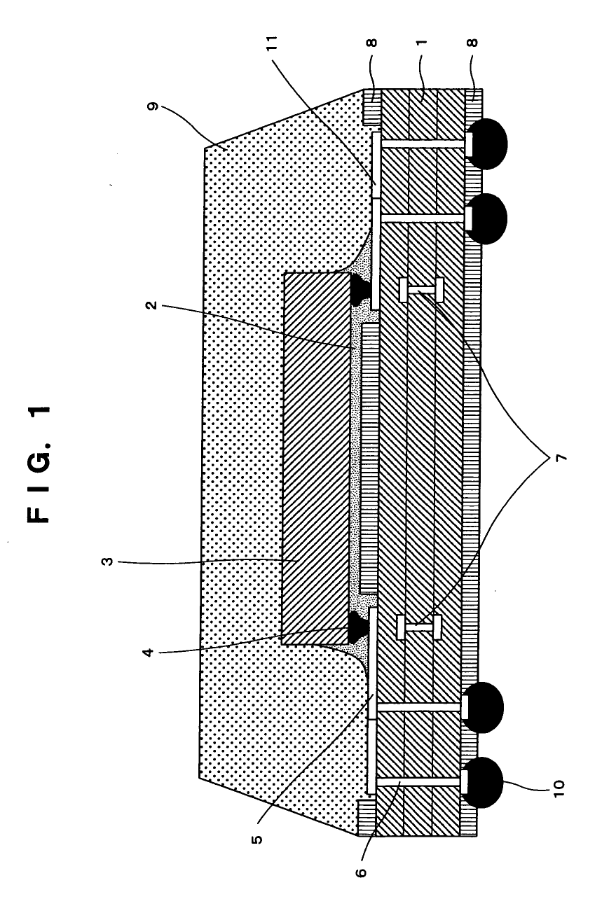

FIG. 1 is a sectional view showing the configuration of a semiconductor device according to Embodiment 1 of the present invention.

As shown in FIG. 1, resist 8 and a wiring circuit 11 including connecting electrodes 5 are disposed on one main surface of a substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having connecting terminals 4 is mounted facedown on the substrate 1. The semiconductor element 3 is mounted as follows: the semiconductor element 3 having the connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6 and electrically connected to the corresponding connecting electrodes, and reinforcing vias 7 which are disposed below any ones of the connecting electrodes 5 and inside one main surface of the substrate 1 to provide electrical insulation.

Since the reinforcing vias 7 are disposed below the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a necessary wiring density. The semiconductor element 3 is 30 μm to 200 μm in thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

As described above, in the semiconductor device configured thus, since the reinforcing vias 7 are disposed below the connecting electrodes 5 and in the substrate 1, the sinking of the connecting electrodes 5 is reduced. The sinking is caused by a load for connecting the semiconductor element 3 to the substrate 1. Since the sinking of the connecting electrodes 5 is reduced during the connection of the semiconductor element 3, the connecting stress of the semiconductor device decreases and the deformation of a joint can be reduced. Thus, it is possible to reduce energy required for connecting the semiconductor element 3 and reduce damage and deformation on the semiconductor element 3. It is therefore possible to achieve connection with a light load and small deformation, thereby easily performing a process design when mounting the semiconductor element 3 on the substrate 1. Moreover, since the reinforcing vias 7 are electrically isolated and are not exposed on the surface of the substrate 1, the electrical characteristics and appearance of the semiconductor device are not different from those of a conventional semiconductor device.

With this configuration, the connecting stress of the semiconductor device and the deformation of a joint can be reduced, and thus it is possible to strengthen the substrate and reduce a bonding load even when the bonding load increases with an increasing number of the connecting terminals 4, so that the packaging process design of the semiconductor element can be easily performed and the semiconductor device can be made more reliable.

### Embodiment 2

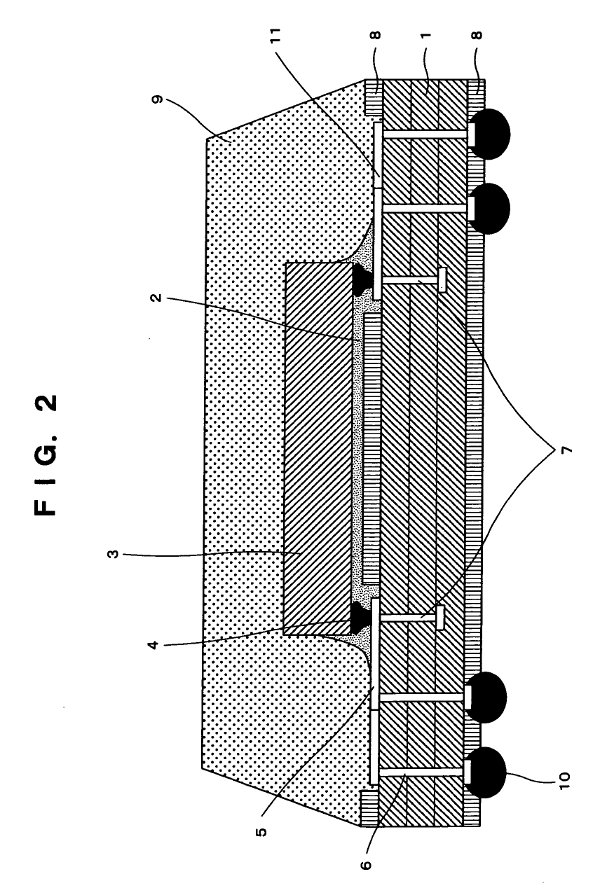

FIG. 2 is a sectional view showing the configuration of a semiconductor device according to Embodiment 2 of the present invention.

According to Embodiment 2, in the semiconductor device of Embodiment 1, reinforcing vias 7 are extended directly below connecting terminals 4 but do not reach the other main surface of a substrate 1.

As shown in FIG. 2, resist 8 and a wiring circuit 11 including connecting electrodes 5 are disposed on one main surface of the substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having the connecting terminals 4 is mounted facedown on the substrate 1. The semiconductor element 3 is mounted as follows: the semiconductor element 3 having the connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6, and the reinforcing vias 7 which are extended below the connecting electrodes 5 but do not reach the other main surface of the substrate 1.

Since the reinforcing vias 7 are disposed below the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a necessary wiring density. The semiconductor element 3 is 30 μm to 200 μm in thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

As described above, the reinforcing vias 7 are directly connected to the connecting electrodes 5 and are longer than those of Embodiment 1. Thus, the sinking of the connecting electrodes is further reduced and the warpage of the substrate 1 and the semiconductor element 3 further decreases due to smaller deformation. Further, more direct reinforcing effect can be obtained by directly connecting the reinforcing vias 7 and the connecting electrodes 5. Since the reinforcing vias do not reach the side of the external terminals, the number of external terminals is not limited. As described above, since the sinking of the connecting electrodes 5 is further reduced during the connection of the semiconductor element 3 as compared with Embodiment 1, the connecting stress of the semiconductor device decreases and the deformation of a joint can be reduced. Thus, it is possible to reduce energy required for connecting the semiconductor element 3 and reduce damage and deformation of the semiconductor element 3. It is therefore possible to achieve connection with a light load and small deformation, thereby easily performing a process design when mounting the semiconductor element 3 on the substrate 1.

With this configuration, it is possible to strengthen the substrate and reduce a bonding load even when the bonding load increases with an increasing number of the connecting terminals 4, so that the packaging process design of the semiconductor element can be easily performed and the semiconductor device can be made more reliable.

In this embodiment, the reinforcing vias 7 may be electrically connected to the connecting electrodes 5. An increase in regulated resistance of the connecting electrodes can be reduced by insulating the reinforcing vias 7.

### Embodiment 3

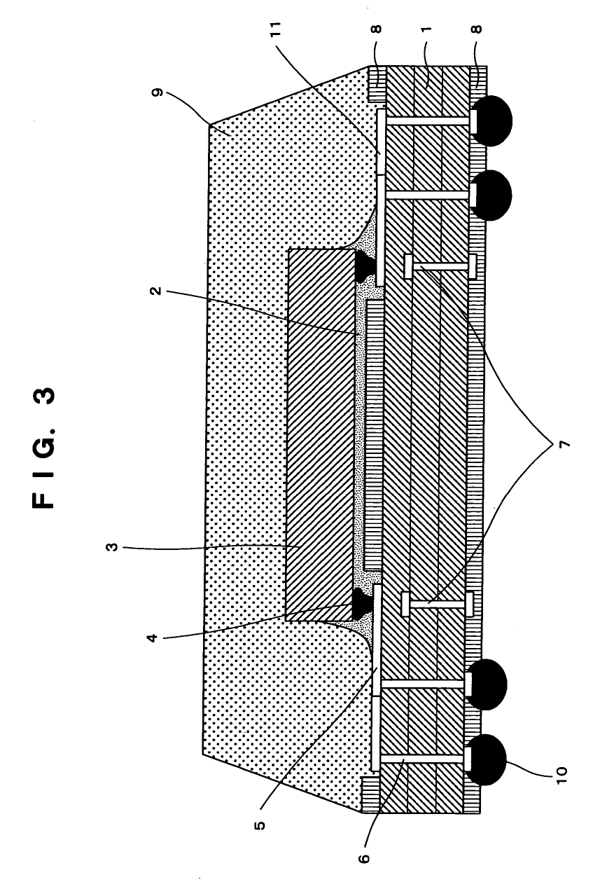

FIG. 3 is a sectional view showing the configuration of a semiconductor device according to Embodiment 3 of the present invention.

According to Embodiment 3, in the semiconductor device of Embodiment 1, reinforcing vias 7 are extended to the other main surface of a substrate 1. The reinforcing vias 7 and connecting electrodes 5 are electrically insulated from each other.

As shown in FIG. 3, resist 8 and a wiring circuit 11 including the connecting electrodes 5 are disposed on one main surface of the substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having the connecting terminals 4 is mounted facedown on the substrate 1. The semiconductor element 3 is mounted as follows: the semiconductor element 3 having the connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6, and the reinforcing vias 7 which are extended to the other main surface of the substrate 1. The reinforcing vias 7 and the connecting electrodes 5 are electrically insulated from each other.

Since the reinforcing vias 7 are disposed below the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a necessary wiring density. The semiconductor element 3 is 30 μm to 200 μm in thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

As described above, the reinforcing vias 7 are longer than those of Embodiment 1. Thus, the sinking of the connecting electrodes is further reduced and the warpage of the substrate 1 and the semiconductor element 3 further decreases due to smaller deformation. Since the reinforcing vias reach the side of the external terminals, external terminals may be provided to improve heat dissipation for the packaging substrate and reinforce connection. As described above, since the sinking of the connecting electrodes 5 is reduced during the connection of the semiconductor element 3 as compared with Embodiment 1, the connecting stress of the semiconductor device and the deformation of a joint can be reduced. Thus, it is possible to reduce energy required for connecting the semiconductor element 3 and reduce damage and deformation of the semiconductor element 3. It is therefore possible to achieve connection with a light load and small deformation, thereby easily performing a process design when mounting the semiconductor element 3 on the substrate 1.

With this configuration, it is possible to strengthen the substrate and reduce a bonding load even when the bonding load increases with an increasing number of the connecting terminals 4, so that the packaging process design of the semiconductor element can be easily performed and the semiconductor device can be made more reliable.

### Embodiment 4

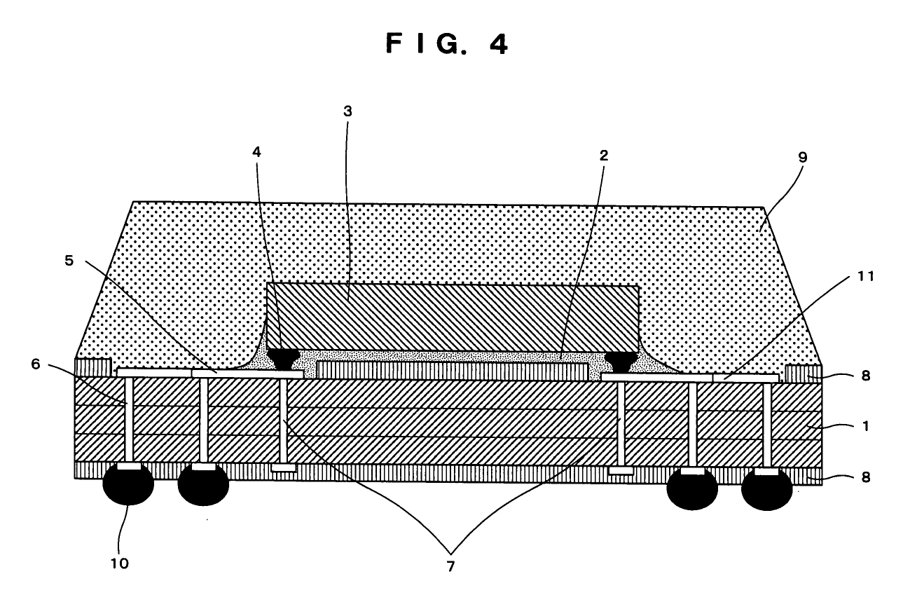

FIG. 4 is a sectional view showing the configuration of a semiconductor device according to Embodiment 4 of the present invention.

According to Embodiment 4, in the semiconductor device of Embodiment 1, reinforcing vias 7 are connected to connecting electrodes 5 and wired to the other main surface of a substrate 1.

As shown in FIG. 4, resist 8 and a wiring circuit 11 including the connecting electrodes 5 are disposed on one main surface of the substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having the connecting terminals 4 is mounted facedown on the substrate 1. The semiconductor element 3 is mounted as follows: the semiconductor element 3 having the connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6, and the reinforcing vias 7 which are extended under the connecting electrodes 5 and reach the other main surface of the substrate 1.

Since the reinforcing vias 7 are disposed under the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a required wiring density. The semiconductor element 3 is 30 μm to 200 min thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

As described above, the reinforcing vias 7 are directly connected to the connecting electrodes 5 unlike Embodiment 1 and the reinforcing vias 7 are longer than those of Embodiment 2, thereby further reducing the sinking of the connecting electrodes. Moreover, since the reinforcing vias 7 penetrate the substrate 1, greater reinforcing effect can be obtained as compared with other embodiments and the warpage of the substrate 1 and the semiconductor element 3 can further decrease due to smaller deformation. As described above, since the sinking of the connecting electrodes 5 is further reduced during the connection of the semiconductor element 3 as compared with Embodiment 1, the connecting stress of the semiconductor device decreases and the deformation of a joint can be reduced. Thus, it is possible to reduce energy required for connecting the semiconductor element 3 and reduce damage and deformation of the semiconductor element 3. It is therefore possible to achieve connection with a light load and small deformation, thereby easily performing a process design when mounting the semiconductor element 3 on the substrate 1.

With this configuration, it is possible to strengthen the substrate and reduce a bonding load even when the bonding load increases with an increasing number of the connecting terminals 4, so that the packaging process design of the semiconductor element can be easily performed and the semiconductor device can be made more reliable.

The same effect can be obtained regardless of whether the reinforcing vias 7 and the connecting electrodes 5 are insulated or electrically connected.

### Embodiment 5

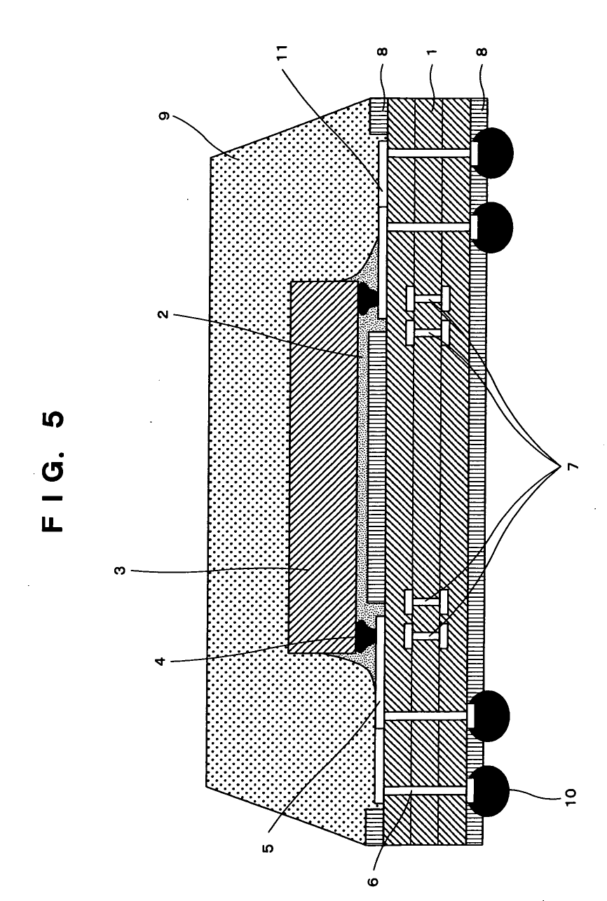

FIG. 5 is a sectional view showing the configuration of a semiconductor device according to Embodiment 5 of the present invention.

As shown in FIG. 5, resist 8 and a wiring circuit 11 including connecting electrodes 5 are disposed on one main surface of a substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having the connecting terminals 4 is mounted facedown on the substrate 1. The semiconductor element 3 is mounted as follows: the semiconductor element 3 having connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6, and reinforcing vias 7 in two or more rows which are disposed below the connecting electrodes 5 and inside one main surface of the substrate 1 and electrically insulated from the connecting electrodes 5.

Since the reinforcing vias 7 are disposed below the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a required wiring density. The semiconductor element 3 is 30 μm to 200 μm in thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

As described above, the number of rows of the reinforcing vias 7 is larger than that of Embodiment 1, thereby further reducing the sinking of the connecting electrodes. The warpage of the substrate 1 and the semiconductor element 3 can further decrease due to smaller deformation. Since the reinforcing vias do not reach the side of the external terminals, the number of external terminals is not limited. As described above, since the sinking of the connecting electrodes 5 is further reduced during the connection of the semiconductor element 3 as compared with Embodiment 1, the connecting stress of the semiconductor device decreases and the deformation of a joint can be reduced. Thus, it is possible to reduce energy required for connecting the semiconductor element 3 and reduce damage and deformation of the semiconductor element 3. It is therefore possible to achieve connection with a light load and small deformation, thereby easily performing a process design when mounting the semiconductor element 3 on the substrate 1.

With this configuration, it is possible to strengthen the substrate and reduce a bonding load even when the bonding load increases with an increasing number of the connecting terminals 4, so that the packaging process design of the semiconductor element can be easily performed and the semiconductor device can be made more reliable.

In a development (not shown) of the present embodiment, the reinforcing vias 7 below the connecting electrodes 5 and inside one main surface of the substrate 1 may be disposed for every two connecting electrodes 5 or every three connecting electrodes 5. In other words, the reinforcing via 7 may be disposed below one of the connecting electrodes 5 but not disposed below an adjacent connecting electrode 5.

Further, the plurality of reinforcing vias 7 according to any one of Embodiments 1 to 4 may be used in the present embodiment.

### Embodiment 6

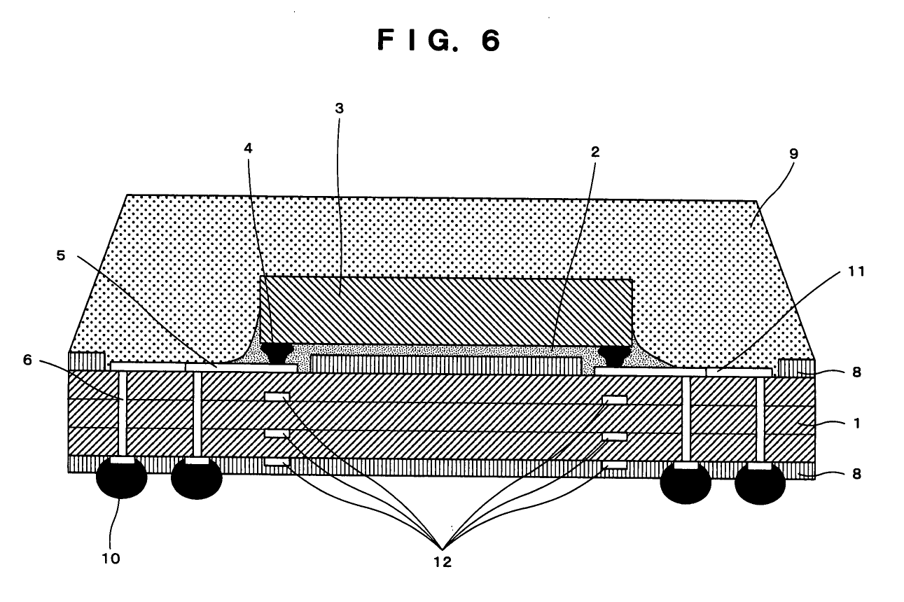

FIG. 6 is a sectional view showing the configuration of a semiconductor device according to Embodiment 6 of the present invention.

As shown in FIG. 6, resist 8 and a wiring circuit 11 including connecting electrodes 5 are disposed on one main surface of a substrate 1. The resist 8 may cover the wiring circuit 11 other than the connecting electrodes 5 or the wiring circuit 11 may be exposed. It is desirable to form the resist 8 on the wiring circuit 11 so thick as to cause no pin holes or the like on the resist 8, to be specific, with a thickness of 10 μm or more. A semiconductor element 3 having the connecting terminals 4 is mounted facedown on the substrate 1. The semiconductor element 3 is mounted as follows: the semiconductor element 3 having connecting terminals 4 is mounted facedown, the connecting terminals 4 being connected to pads on the semiconductor element 3 by a wire bonding device, the substrate 1 is pressed with a force of 20 gf or more for each of the connecting terminals 4 while being heated, thermosetting resin 2 interposed between the semiconductor element 3 and the substrate 1 is cured by the heat while the warpage of the substrate 1 is corrected, and the semiconductor element 3 and the substrate 1 are connected so as to electrically connect the connecting terminals 4 and the connecting electrodes 5. In this case, the connecting terminals 4 are made of Au and may be formed using solder, Cu, or resin bumps. In order to further improve the connecting characteristic, base resin melting at low temperature may be used. The thermosetting resin 2 may be applied or bonded before or after the semiconductor element 3 is mounted.

The semiconductor element 3 having the connecting terminals 4 is mounted facedown on the substrate 1, and the connecting electrodes 5 and the connecting terminals 4 are electrically connected to each other. The substrate 1 comprises connecting vias 6 which are electrically connected in the substrate 1 to the connecting electrodes 5 and the wiring circuit 11, external terminals 10 which are connected to the connecting vias 6, and reinforcing metal layers 12 which act as reinforcing layers, disposed below the connecting electrodes 5 and inside one main surface of the substrate 1, and electrically insulated from the connecting electrodes 5.

Since the reinforcing metal layers 12 are disposed below the connecting electrodes 5, it is possible to reduce the sinking of the connecting electrodes 5 when applying pressure for mounting the semiconductor element 3.

The external terminals 10 connected to the connecting vias 6 are disposed on the opposite surface from one main surface of the substrate 1 where the semiconductor element 3 is mounted. The external terminals 10 are generally solder balls or the like but may be metallic balls other than solder balls or lands/bumps not shaped like balls.

The mounting surface for mounting the semiconductor element 3 on the substrate 1 is sealed with molding resin 9 which covers the semiconductor element 3, the connecting terminals 4, the connecting electrodes 5, and the wiring circuit 11.

In this case, the substrate 1 includes a fiber reinforced resin layer made of glass cloth laminated epoxy, nonwoven aramid fabric, and so on. Further, the number of layers in the substrate 1 is suitably set at four to six according to a required wiring density. The semiconductor element 3 is 30 μm to 200 μm in thickness and the substrate 1 is 260 μm to 350 μm in thickness in many cases. The wiring circuit of the substrate 1 is about 5 μm to 20 μm in thickness, an inner layer wire is made of a material such as Cu and Cu—Ni, and a surface wire is made of a material such as Cu—Ni—Au. The connecting terminals 4 have a pitch of 60 μm to 80 μm, and the pitch of the connecting terminals 4 has been reduced. Further, the connecting terminals 4 have been arranged alternately or arranged in a lattice form (area layout).

According to the present embodiment, since a number of reinforcing metal layers 12 can be disposed, it is possible to reduce the sinking of the connecting electrodes, and the warpage of the substrate 1 and the semiconductor element 3 can further decrease due to smaller deformation. Unlike Embodiment 1, the present embodiment has no via structure and thus the substrate can be manufactured with ease. The reinforcing metal layers 12 may be disposed so as to correspond to the respective connecting electrodes 5 or the reinforcing metal layer 12 may be shaped like a strip or a ring over the underside of the connecting electrode 5 (not shown). As described above, since the sinking of the connecting electrodes is reduced during the connection of the semiconductor element 3, the connecting stress of the semiconductor device decreases and the deformation of a joint can be reduced. Thus, it is possible to reduce energy required for connecting the semiconductor element 3 and reduce damage and deformation of the semiconductor element 3. It is therefore possible to achieve connection with a light load and small deformation, thereby easily performing a process design when mounting the semiconductor element 3 on the substrate 1.

With this configuration, it is possible to strengthen the substrate and reduce a bonding load even when the bonding load increases with an increasing number of the connecting terminals 4, so that the packaging process design of the semiconductor element can be easily performed and the semiconductor device can be made more reliable.

The reinforcing vias and the reinforcing metal layers of the foregoing embodiments can be formed below any ones of the connecting electrodes and may be formed below all or some of the plurality of connecting electrodes.

The above explanation described as an example of the semiconductor device comprising a single semiconductor element. Also in the case of a semiconductor device comprising two or more semiconductor elements, reinforcing vias or reinforcing metal layers can be formed below any ones of connecting electrodes.

In the foregoing embodiments, the reinforcing metal layer is used as a reinforcing layer. The layer does not always have to be made of a metal and thus may be made of an insulating material having higher stiffness than the substrate.

Although it is preferable to dispose the reinforcing vias 7 immediately under the connecting terminals 4 susceptible to stress, the positions are not particularly limited. The reinforcing vias 7 may be disposed anywhere as long as the sinking of the connecting electrodes 5 can be reduced. In front view, although the reinforcing via 7 is shaped like letter H laid down lengthwise to receive a load or the reinforcing via 7 is shaped like reversed letter T to support the connecting electrode 5, the reinforcing via 7 is not limited to such configurations.

As described above, according to the present invention, one or more reinforcing vias or reinforcing metal layers are disposed on the inner side of the connecting electrodes, so that strength increases relative to a load applied for mounting the semiconductor element and the sinking of the connecting electrodes is reduced. Thus, it is possible to reduce the connecting stress of the semiconductor device, reduce the deformation of a joint, and increase flexibility in process design.

The present invention is useful for a semiconductor device or the like which makes it possible to reduce the connecting stress of the semiconductor device, reduce the deformation of a joint, protect the integrated circuit of an LSI chip, obtain stable electrical connection between an external device and the LSI chip, and achieve high-density packaging.

What is claimed is:

1. A semiconductor device, in which at least one semiconductor element is mounted facedown on a substrate, the semiconductor element including a plurality of connecting terminals, wherein
the substrate comprises:
a plurality of connecting electrodes formed on one main surface of the substrate electrically connected to the connecting terminals,
a plurality of external terminals formed on the other main surface of the substrate,
a plurality of connecting vias for electrically connecting the external terminals and the corresponding connecting electrodes, and
reinforcing vias formed in an area under the connecting electrodes other than areas where the connecting vias are formed in the substrate.

2. The semiconductor device according to claim 1, wherein the reinforcing vias are wired to the other main surface of the substrate.

3. The semiconductor device according to claim 1, wherein the two or more reinforcing vias are formed for each of the connecting electrodes.

4. The semiconductor device according to claim 1, wherein the reinforcing vias are connected in an electrically insulated manner from the connecting electrodes.

5. The semiconductor device according to claim 4, wherein the reinforcing vias are wired to the other main surface of the substrate.

6. The semiconductor device according to claim 4, wherein the two or more reinforcing vias are formed for each of the connecting electrodes.

7. The semiconductor device according to claim 1, wherein the reinforcing vias are electrically connected to the connecting electrodes.

8. The semiconductor device according to claim 7, wherein the two or more reinforcing vias are formed for each of the connecting electrodes.

9. The semiconductor device according to claim 7, wherein the reinforcing vias are wired to the other main surface of the substrate.

10. The semiconductor device according to claim 9, wherein the two or more reinforcing vias are formed for each of the connecting electrodes.

11. A semiconductor device, in which at least one semiconductor element is mounted facedown on a substrate, the semiconductor element including a plurality of connecting terminals, wherein
the substrate comprises:
a plurality of connecting electrodes formed on one main surface of the substrate electrically connected to the connecting terminals,
a plurality of external terminals formed on the other main surface of the substrate,
a plurality of connecting vias for electrically connecting the external terminals and the corresponding connecting electrodes, and
at least one reinforcing metal layer formed to be electrically insulated in an area under the connecting electrodes in the substrate.

12. The semiconductor device according to claim 11, wherein the reinforcing layer is made of a metal.

13. The semiconductor device according to claim 11, wherein the reinforcing layer is made of an insulating material.
